(19) United States
(12) Patent Application Publication
(10) Pub. No.: US 2023/0178669 A1
(43) Pub. Date: Jun. 8, 2023

(54) PHOTOVOLTAIC STRING AND ASSOCIATED METHODS

(71) Applicant: COMMISSARIAT A L'ENERGIE ATOMIQUE ET AUX ENERGIES ALTERNATIVES, PARIS (FR)

(72) Inventor: Armand BETTINELLI, GRENOBLE CEDEX 09 (FR)

(21) Appl. No.: 17/927,636

(22) PCT Filed: May 26, 2021
(86) PCT No.: PCT/EP2021/063986

§ 371 Date: Nov. 23, 2022

(30) Foreign Application Priority Data
May 27, 2020 (FR) FR2005602

(51) Int. Cl. H01L 31/05; H01L 31/18

(52) U.S. Cl. CPC H01L 31/0504; H01L 31/1876

(57) ABSTRACT

A photovoltaic string includes a plurality of photovoltaic shingle and a metallic connector; the shingle being glued in pairs, forming a plurality of overlapping surfaces, each overlapping surface having an overlap width, the metallic connector being glued or welded to an end shingle forming a transfer surface, the transfer surface having a transfer width greater than or equal to each of the overlap widths, the active surface of the end shingle preferably being greater than or equal to the active surface of an intermediate shingle.

### TECHNICAL FIELD OF THE INVENTION

The technical field of the invention is that of photovoltaic cell strings and in particular the connection of said strings to a metallic connector.

### TECHNOLOGICAL BACKGROUND OF THE INVENTION

A photovoltaic string is made by the series interconnection of a plurality of photovoltaic cells forming a photovoltaic cell chain, each end of the photovoltaic cell chain being connected to a metallic connector. Thus formed, the photovoltaic string can be connected within an electrical grid and provide electrical energy to the electrical grid. The method commonly used for forming photovoltaic strings is welding or bonding ribbons or wires to collection electrodes on the front face of a first photovoltaic cell and to collection electrodes on the back face of an adjacent second photovoltaic cell. The first and second photovoltaic cells are separated by a few millimeters, about 3 mm, so that the ribbon or wire can change planes from the front face of the first photovoltaic cell to the back face of the second photovoltaic cell. The spacing between the photovoltaic cells increases the surface area of the photovoltaic string thus formed.

There is a technique for interconnecting photovoltaic cells called “shingle” that does not use ribbons or wires to address the increased surface area of the photovoltaic string. The “shingle” interconnection technique is for example described in the article [“Materials challenge for shingled cells interconnection”, G. Beaucarne, Energy Procedia 98, pp. 115-124, 2016]. The photovoltaic cells forming the photovoltaic chain are superimposed on each other, with a lower photovoltaic cell partially covered with an adjacent upper photovoltaic cell, in the same way that shingles cover a roof. The interconnection between two adjacent photovoltaic cells is made in the coverage zone. The front face of the lower photovoltaic cell and the back face of the upper photovoltaic cell each include an array of collection electrodes connected to an interconnection track, extending along one edge. During interconnection of the photovoltaic chain, the two interconnection tracks are electrically and mechanically connected by welding or bonding. The shingle interconnected photovoltaic chain thus eliminates the separation between the photovoltaic cells, providing a continuous active surface area over the entire surface of the photovoltaic string.

The photovoltaic chain is also electrically and mechanically connected to the metallic connectors by transferring one of the metallic connectors to each end photovoltaic cell of the photovoltaic chain. Current interconnection technologies, especially those that implement bonding using an electrically conductive adhesive, have made interconnection between photovoltaic cells more reliable while reducing the coverage surface areas between two consecutive cells. The interconnections between cells are then able to withstand stresses of seasonal thermal expansions.

On the other hand, connections of the metallic connectors with the end photovoltaic cells of the photovoltaic chain pose reliability problems.

### SUMMARY OF THE INVENTION

One purpose of the invention is to make the electrical and mechanical connection of metallic connectors within a photovoltaic string more reliable.

A first aspect of the invention relates to a photovoltaic string comprising:
a first photovoltaic cell called a first end shingle;
a second photovoltaic cell called a second end shingle; and
a plurality of third photovoltaic cells called intermediate shingles, disposed between the first and second end shingles; and
a first metallic connector;
   each of the first, second and third photovoltaic cells comprising a front face and a back face opposite to the front face, the first end shingle, the intermediate shingles and the second end shingle being interconnected by means of a first electrically conductive adhesive, the first end shingle being interconnected to a first intermediate shingle, the back face of the first end shingle covering a surface of the front face of the first intermediate shingle, called a first coverage surface, the first coverage surface having a first coverage width, the second end shingle being interconnected to a second intermediate shingle, the back face of the second intermediate shingle covering a surface of the front face of the second end shingle, called the second coverage surface, the second coverage surface having a second coverage width, the first metallic connector being connected to the first end shingle by means of a second electrically conductive adhesive, the first metallic connector covering a surface of the front face of the first end shingle, called the first transfer surface, the first transfer surface having a first transfer width greater than each of the first and second coverage width.

Thus, increasing the transfer width of the connectors makes the mechanical, and thus electrical, connection of the photovoltaic string more reliable, while maintaining a single adhesion technology, by bonding.

In addition to the characteristics just discussed in the preceding paragraph, the photovoltaic string according to the first aspect of the invention may have one or more complementary characteristics from among the following, considered individually or according to all technically possible combinations.

Advantageously, the intermediate shingles are interconnected in pairs, for each intermediate shingle interconnected in pairs, the back face of a first intermediate shingle covers the front face of a second intermediate shingle, covering a surface of the second intermediate shingle.

Preferably, the short circuit current on the front face of the first end shingle when the first transfer surface is masked is greater than or equal to the short circuit current on the front face of an intermediate shingle when its coverage surface is masked.

Advantageously, the short circuit current on the front face of the first end shingle when its front face is fully exposed is greater than the short circuit current on the front face of the intermediate shingle when its front face is fully exposed.

Advantageously, the active surface area on the front face of the first end shingle is greater than or equal to the active surface area on the front face of the intermediate shingle.

Advantageously, the width of the first end shingle is greater than the width of the intermediate shingle.

Advantageously, the front face of the first end shingle comprises an interconnection conductor track extending into the first transfer surface, the interconnection conductor track comprising a plurality of spaced-apart closed-contour conductor patterns, each closed-contour conductor pattern comprising a closed contour surrounding a portion of the front face, at least some of the closed-contour conductor patterns each containing a portion of the second electrically conductive adhesive adhering to the portion of the front face and to the first metallic connector.

Advantageously, the interconnection conductor track comprises a conductor line electrically connecting two consecutive closed-contour conductor patterns.

Advantageously, the first metallic connector comprises a plurality of disjointed portions connected to the first end shingle, each portion of the first metallic connector covering a surface of the front face of the first end shingle, called a portion of the first transfer surface, each portion of the first transfer surface having a transfer width greater than each of the first and second coverage widths.

Advantageously, the photovoltaic string further comprises:
a second metallic connector;
   the second metallic connector being connected to the second end shingle by means of the second electrically conductive adhesive, the second metallic connector covering a surface of the back face of the second end shingle, called the second transfer surface, the second transfer surface having a second transfer width greater than each of the first and second coverage widths.

Advantageously, the short circuit current on the back face of the second end shingle when the second transfer surface is masked is greater than or equal to the short circuit current on the back face of an intermediate shingle when its coverage surface is masked.

A second aspect of the invention relates to a method for manufacturing a photovoltaic string comprising the following steps:
providing a first photovoltaic cell called a first end shingle, a second photovoltaic cell called a second end shingle, a plurality of third photovoltaic cells called intermediate shingles and a first metallic connector, each of the first, second and third photovoltaic cells comprising a front face and a back face opposite to the front face;
interconnecting the first end shingle to a first intermediate shingle by means of a first electrically conductive adhesive, the back face of the first end shingle covering a surface of the front face of the first intermediate shingle, called a first coverage surface, the first coverage surface having a first coverage width;
interconnecting a second intermediate shingle to the second end shingle by means of the first electrically conductive adhesive, the back face of the second intermediate shingle covering a surface of the front face of the second end shingle, called the second coverage surface, the second coverage surface having a second coverage width;
connecting the first metallic connector to the first end shingle by means of a second electrically conductive adhesive, the first metallic connector covering a surface of the front face of the first end shingle, called a first transfer surface, the first transfer surface having a first transfer width greater than each of the first and second coverage widths.

A third aspect of the invention relates to a photovoltaic string comprising:
a first photovoltaic cell called a first end shingle;
a second photovoltaic cell called a second end shingle; and
a plurality of third photovoltaic cells called intermediate shingles, disposed between the first and second end shingles; and
a first metallic connector;
   each of the first, second and third photovoltaic cells comprising a front face and a back face opposite to the front face, the first end shingle, the intermediate shingles and the second end shingle being interconnected by means of a first electrically conductive adhesive, the first end shingle being interconnected to a first intermediate shingle, the back face of the first end shingle covering a surface of the front face of the first intermediate shingle, called a first coverage surface, the first coverage surface having a first coverage width, the second end shingle being interconnected to a second intermediate shingle, the back face of the second intermediate shingle covering a surface of the front face of the second end shingle, called the second coverage surface, the second coverage surface having a second coverage width, the first metallic connector being connected to the first end shingle, the first metallic connector covering a surface of the front face of the first end shingle, called the first transfer surface, the first metallic connector being welded to the first end shingle.

The welding thus makes it possible to limit the first and second transfer widths with respect to the connections by means of the second adhesive while making the connections within the photovoltaic string more reliable. Keeping a bonding at the interconnections of the intermediate shingles, which is more ductile than a welding joint, makes it possible to absorb the deformations dictated by the expansion of the shingles. The reliability of the photovoltaic string with respect to daily and seasonal expansion is thus improved.

In addition to the characteristics just discussed in the preceding paragraph, the photovoltaic string according to the third aspect of the invention may have one or more of the following additional characteristics, considered individually or in any technically possible combination.

Advantageously, the first transfer surface has a first transfer width substantially equal to the first and second coverage widths.

Advantageously, the front face of the first end shingle comprises an interconnection conductor track extending on the first transfer surface, the first metallic connector being welded to the interconnection conductor track.

Advantageously, the interconnection conductor track is continuous.

Advantageously, the interconnection conductor track comprises a plurality of disjointed portions, each portion being welded to the first metallic connector.

Advantageously, the interconnection conductor track comprises a conductor line electrically connecting two consecutive portions of the interconnection conductor track.

Advantageously, the active surface area on the front face of the first end shingle is greater than or equal to the active surface area on the front face of an intermediate shingle.

Advantageously, the first metallic connector comprises a plurality of disjointed portions welded to the first end shingle, each portion of the first metallic connector covering a surface of the front face of the first end shingle, called a portion of the first transfer surface.

Advantageously, each portion of the first transfer surface has a transfer width greater than each of the first and second coverage widths.

Advantageously, the photovoltaic string further comprises:
a second metallic connector;
   the second metallic connector being welded to the second end shingle, the second metallic connector covering a surface of the back face of the second end shingle, called the second transfer surface, the second metallic connector being welded to the second end shingle.

Advantageously, the second transfer surface having a second transfer width substantially equal to the second coverage width.

A fourth aspect of the invention relates to a method for manufacturing a photovoltaic string comprising the following steps:
providing a first photovoltaic cell called a first end shingle, a second photovoltaic cell called a second end shingle, a plurality of third photovoltaic cells called intermediate shingles, and a first metallic connector, each of the first, second, and third photovoltaic cells comprising a front face and a back face opposite to the front face;
interconnecting the first end shingle to a first intermediate shingle by means of a first electrically conductive adhesive, the back face of the first end shingle covering a first surface of the front face of the first intermediate shingle, called a first coverage surface, the first coverage surface having a first coverage width;
interconnecting a second intermediate shingle to the second end shingle by means of the first electrically conductive adhesive, the back face of the second intermediate shingle covering a surface of the front face of the second end shingle, called a second coverage surface, the second coverage surface having a second coverage width;
welding the first metallic connector to the first end shingle, the first metallic connector covering a surface of the front face of the first end shingle, called a first transfer surface.

A fifth aspect of the invention relates to a photovoltaic string comprising:
a first photovoltaic cell called a first end shingle;
a second photovoltaic cell called a second end shingle; and
a plurality of third photovoltaic cells called intermediate shingles, disposed between the first and second end shingles; and
a first metallic connector comprising a plurality of disjointed portions;
   each of the first, second and third photovoltaic cells comprising a front face and a back face opposite to the front face, the first end shingle, the intermediate shingles and the second end shingle being interconnected by means of a first electrically conductive adhesive, the first end shingle being interconnected to a first intermediate shingle, the back face of the first end shingle covering a surface of the front face of the first intermediate shingle, called a first coverage surface, the first coverage surface having a first coverage width, the second end shingle being interconnected to a second intermediate shingle, the back face of the second intermediate shingle covering a surface of the front face of the second end shingle, called a second coverage surface, the second coverage surface having a second coverage width, each disjointed portion of the first metallic connector being connected to the first end shingle, each disjointed portion of the first metallic connector covering a surface of the front face of the first end shingle, called a portion of the first transfer surface, each portion of the first transfer surface having a transfer width greater than each of the first and second coverage width.

The invention and its various applications will be better understood upon reading the following description and examining the accompanying figures.

### BRIEF DESCRIPTION OF THE FIGURES

The figures are set forth as an indication and in no way as a limitation of the invention.

FIG. 1 schematically represents, in side view and top view, a first embodiment of a photovoltaic string according to the first aspect of the invention.

FIG. 2 schematically represents, in bottom view, a second embodiment of a photovoltaic string according to the first aspect of the invention.

FIG. 3 schematically represents a first end shingle of the photovoltaic string according to a third embodiment, the first end shingle being connected to a first metallic connector

FIG. 4 schematically represents the first end shingle of the photovoltaic string according to the third embodiment, without the first metallic connector.

FIG. 5 schematically represents the first end shingle of the photovoltaic string according to the third embodiment, with the figure centred on two closed-contour conductor patterns.

FIG. 6 schematically represents the first end shingle of the photovoltaic string according to a fourth embodiment, with the figure centred on two closed-contour conductor patterns.

FIG. 7 schematically represents the photovoltaic string according to a fifth embodiment.

FIG. 8 schematically represents a method for manufacturing, according to the second aspect of the invention, the photovoltaic string according to the first aspect of the invention.

FIG. 9 schematically represents in side view and top view, a first embodiment of a photovoltaic string according to the third aspect of the invention.

FIG. 10 schematically represents a second embodiment of the photovoltaic string according to the third aspect of the invention, the figure being centred on a first end shingle.

FIG. 11 schematically represents a third embodiment of the photovoltaic string according to the third aspect of the invention, the figure being centred on a first end shingle.

FIG. 12 schematically represents a method for manufacturing, according to the fourth aspect of the invention, the photovoltaic string according to the third aspect of the invention.

### DETAILED DESCRIPTION

The figures are set forth as an indication and in no way as a limitation of the invention. Unless otherwise specified, a same element appearing in different figures has a unique reference.

### Bonded Photovoltaic String

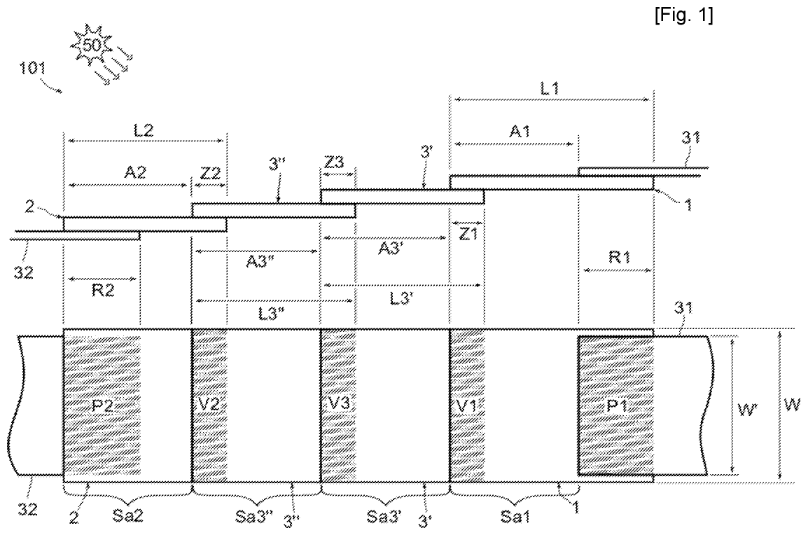

FIG. 1 schematically represents a first embodiment of a photovoltaic string 101 according to a first aspect of the invention.

The photovoltaic string 101 comprises:
a first photovoltaic cell 1 called a first end shingle;
a second photovoltaic cell 2 called a second end shingle; and
two third photovoltaic cells 3′, 3″ called intermediate shingles;
a first metallic connector 31 (also called first metal connector); and
a second metallic connector 32 (also called second metal connector).

The photovoltaic string 101 comprises two intermediate shingles 3′, 3″, however the photovoltaic string 101 preferably comprises more than two intermediate shingles 3′, 3″, for example about thirty.

The first and second end shingles 1, 2 and the third photovoltaic intermediate shingles 3′, 3″ are made from semiconductor substrates, for example silicon, which allow light radiation, for example solar radiation, to be converted into electrical energy. The substrates implement so-called homojunction or heterojunction technologies. The surfaces of the shingles 1, 2, 3′, 3″ preferably comprise an insulating layer, for example made of SiN, or a layer of transparent conductive oxide (TCO), for example made of indium-tin oxide.

The shingles 1, 2, 3′, 3″ can have a square shape, for example 156 mm long and 156 mm wide, or preferably a rectangular shape, for example 156 mm long and 31.2 mm wide or 156 mm long and 26 mm wide. All shingles 1, 2, 3′, 3″ within a photovoltaic string 101 preferably have the same shape and length W.

Each of the first and second end shingles 1, 2 and the third intermediate photovoltaic shingles 3′, 3″ comprises a front face and a back face opposite to the front face. The front face comprises:
an interconnection conductor track; and
a plurality of collection electrodes called “collection fingers”.

The collection fingers are intended to collect the electric currents produced by each photovoltaic cell 1, 2, 3′, 3″. The collection fingers extend in parallel to each other along the front face and are preferably evenly distributed on the front face. In order to carry electric currents through the photovoltaic string 101, the collection fingers are electrically connected to the interconnection conductor track. Each interconnection conductor track preferably extends in parallel to an edge, in the vicinity of this edge, for example to within 1.5 mm of the edge or preferably to within 1.0 mm of the edge.

The back face of each shingle 1, 2, 3′, 3″ further comprises one or more conductive elements that also allow collection of electric currents. This may be a metallisation covering the entire surface of the back face or else collection fingers similar to the collection fingers 5 of the front face. The bifacial shingles, that is, capable of capturing electromagnetic radiation through the back face, preferably comprise collection fingers.

The back face of each shingle 1, 2, 3′, 3″ also comprises an interconnection conductor track allowing the interconnection of the shingles 1, 2, 3′, 3″ to each other. For example, these may be metallised tracks extending along an edge of the back face, in the vicinity of this edge.

The first and second end shingles 1, 2 and intermediate shingles 3′, 3″ are interconnected in series, that is, by electrically connecting the back face of one of said shingles 1, 2, 3′, 3″ with the front face of a consecutive shingle 1, 2, 3′, 3″. The intermediate shingles 3′, 3″ are disposed between the first and second end shingles 1, 2. The interconnection between two consecutive shingles is achieved by means of a first electrically conductive adhesive. The first electrically conductive adhesive provides the electrical connection of the consecutive shingles as well as the mechanical connect between said shingles.

The first end shingle 1 is interconnected to a first intermediate shingle 3′, by electrically connecting the back face of the first end shingle 1 with the front face of the first intermediate shingle 3′. The electrical connection is made without wire or ribbon, by directly connecting, by means of the first electrically conductive adhesive, the interconnection conductor track of the front face and the interconnection conductor track (or full plate metallisation) of the back face. According to this so-called shingle interconnection mode, the back face of the first end shingle 1 covers a surface V1 of the front face of the first intermediate shingle 3′, called the first coverage surface.

Because of the coverage by the first end shingle 1, the first coverage surface V1 is not exposed to light radiation. In FIG. 1, the first coverage surface V1 has a rectangular shape, extending along a covered edge of the first intermediate shingle 3′, preferably over the entire length of this edge. The first coverage surface V1 extends over a first coverage width Z1, measured perpendicular to said covered edge of the first intermediate shingle 3′.

Similarly, the second end shingle 2 is interconnected to a second intermediate shingle 3″, by electrically connecting the front face of the second end shingle 2 with the back face of the second intermediate shingle 3″. The electrical connection is also made by directly connecting, by means of the first electrically conductive adhesive, the interconnection conductor track of the front face and the interconnection conductor track (or full plate metallisation) of the back face. The back face of the second intermediate shingle 3″ covers a surface V2 of the front face of the second end shingle 2, called the second coverage surface.

Like the first coverage surface V1, the second coverage surface V2 has a rectangular shape, extending along a covered edge of the second end shingle 2 and preferably over the entire length of this covered edge. The second coverage surface V2 extends over a second coverage width Z2, measured perpendicular to said covered edge of the second end shingle 2.

The intermediate shingles 3′, 3″ are interconnected to each other and are disposed between the first and second end shingles 1, 2. In FIG. 1 where only two intermediate shingles 3′, 3″ are represented, the first intermediate shingle 3′ is interconnected to the second intermediate shingle 3″, electrically connecting the back face of the first intermediate shingle 3′ with the front face of the second intermediate shingle 3″. The electrical connection is also made by directly connecting the interconnection conductor tracks of each of the front and back faces with the first electrically conductive adhesive. The back face of the first intermediate shingle 3′ covers a surface V3 of the front face of the second intermediate shingle 3″, called the third coverage surface. The third coverage surface V3 extends along a covered edge of the second intermediate shingle 3″ and preferably over the entire length of this covered edge and over a third coverage width Z3, measured perpendicular to said covered edge.

Preferably, the shingles 1, 2, 3′, 3″ are aligned so that the coverage surfaces V1, V2, V3 extend over the entire length of each shingle 1, 2, 3′, 3″.

Preferably, the first, second and third coverage surfaces V1, V2, V3 are substantially equal. By “substantially equal”, it is meant surfaces whose difference does not exceed 5% (V1=V2±5%=V3±5%). This difference corresponds for example to the alignment error of the shingles. Since the first, second and third coverage surfaces V1, V2, V3 preferably extend over the entire length of the covered edges of the intermediate shingles 3′, 3″ and the second end shingle 2, the first, second and third coverage widths Z1, Z2, Z3 are preferably substantially equal (Z1=Z2±5%=Z3±5%).

The photovoltaic string 101 preferably comprises more than two intermediate shingles, for example more than thirty intermediate shingles. According to this alternative, all intermediate shingles are interconnected in series in pairs. For each pair of interconnected intermediate shingles, the back face of a first intermediate shingle is electrically connected with the front face of a second intermediate shingle by means of the first electrically conductive adhesive. The back face of the first intermediate shingle covers a surface V3 of the front face of the second intermediate shingle, called the third coverage surface. The series interconnection of a plurality of intermediate shingles thus forms a plurality of third coverage surfaces V3. Each third coverage surface V3 extends along a covered edge of each second intermediate shingle and preferably over the entire length of this covered edge and over a third coverage width Z3, measured perpendicular to said covered edge. Preferably all third coverage surface areas V3 are substantially equal and even more preferably all third coverage widths Z3 are substantially equal.

The mechanical reliability of the photovoltaic string 101 is highly dependent on the quality of the interconnection between each shingle 1, 2, 3′, 3″. The photovoltaic string 101 undergoes, for example, successive expansions, due to daily and seasonal temperature variations. The successive expansions stress the interconnections.

The first electrically conductive adhesive preferably comprises an organic material capable of crosslinking upon thermal treatment for a few seconds to a few minutes at a temperature between 120° C. and 200° C., such as epoxy, acrylate, or silicone. The organic material is loaded with a conductive material such as a powder of metal or metallised particles on the surface. Copper-based metal particles are not chemically stable enough and are at least coated with a silver layer to stabilize them. Nickel- or silver-based metal particles give the best performance.

The first electrically conductive adhesive advantageously comprises a rate of metal or metallised particles between 50% and 90%, in order to achieve a low-resistive interconnection, especially when the metallised elements of each shingle 1, 2, 3′, 3″ have a small surface area. A metal particle rate of between 50% and 60% provides sufficient electrical conductivity while limiting the cost of the adhesive.

The first electrically conductive adhesive is especially more ductile than a welding joint, thus it can absorb the deformations dictated by the expansion of the shingles 1, 2, 3′, 3″. The reliability of the photovoltaic string 101 with respect to daily and seasonal expansions is thus improved.

In order to provide the electric current due to the conversion of solar radiation within an electrical grid, the end shingles 1, 2 and the intermediate shingles 3′, 3″, interconnected in series, are electrically connected to the first and second metal connectors 31, 32. The first and second metal connectors 31, 32 allow the photovoltaic string 101 to be easily connected in an electrical arrangement.

The first and second metal connectors 31, 32 are respectively connected to the first and second end shingles 1, 2 by means of a second electrically conductive adhesive. The first metal connector 31 is connected to the front face of the first end shingle 1. The first metal connector 31 covers a surface P1 of the front face of the first end shingle 1, called the first transfer surface. The second metal connector 32 is connected to the back face of the second end shingle 2. The second metal connector 32 covers a surface P2 of the back face of the second end shingle 2, called the second transfer surface. The connections are preferably made by directly connecting the first and second connectors 31, 32 respectively to the interconnection conductor track of each of the first and second end shingles 1, 2 with the second electrically conductive adhesive.

The first and second transfer surfaces P1, P2 each have a rectangular shape. They extend over a length W′ along a covered edge of the first end shingle 1 and along a covered edge of the second end shingle 2, respectively. The first transfer surface P1 has a first transfer width R1 measured perpendicular to said edge. The second transfer surface has a second transfer width R2 measured perpendicular to said edge.

The second electrically conductive adhesive may be of the same nature as the first electrically conductive adhesive, that is, comprise a resin and metal or metallised particles. The second electrically conductive adhesive may be identical to the first electrically conductive adhesive. However, the second electrically conductive adhesive preferably comprises anti-corrosion agents for reliable contact with the metal connectors 31, 32, the latter being generally copper-based and coated with an alloy layer, for example tin-lead-silver. The first electrically conductive adhesive does not necessarily include an anti-corrosion agent because the metallisations extending on the surfaces of the shingles 1, 2, 3′, 3″, containing for example silver, do not corrode. The resin can be different in order to promote adhesion to the metal surfaces. For example, it may be more rigid because the need for ductility at the shingle/connector connection is less than at the shingle/shingle. The resin may be epoxy or acrylate based, having two to three times the adhesion to the substrate as compared to adhesion to a metallised zone.

In contrast to the adhesion to the substrate, the second electrically conductive adhesive has limited adhesion to metal surfaces, such as the first and second metal connectors 31, 32. The connection of the first and second metal connectors 31, 32 therefore presents a risk of peeling or tearing.

In order to reduce the risk of peeling and thus make the adhesion of the first metal connector 31 to the first end shingle 1 more reliable, the first transfer width R1 is greater than each of the first and second coverage widths Z1, Z2 and preferably also greater than each of the third coverage widths Z3. Thus, the contact width of the second electrically conductive adhesive between the first end shingle 1 and the first metal connector 31 is increased.

Similarly, in order to make the adhesion of the second metal connector 32 to the second end shingle 2 more reliable, the second transfer width R2 is advantageously greater than each of the first and second coverage widths Z1, Z2 and preferably also greater than each of the third coverage widths Z3.

For example, for coverage widths Z1, Z2, Z3 equal to 0.5 mm within the photovoltaic string 101, the first and second transfer widths R1, R2 for connecting the first and second metal connectors 31, 32 are advantageously equal to 0.9 mm.

Thus, increasing the transfer width of the connectors makes it possible to make the mechanical, and thus electrical, connection of the photovoltaic string 101 more reliable, while keeping a single adhesion technology, by bonding.

In order to reduce the risk of peeling and make the adhesion of the first metal connector 31 to the first end shingle 1 more reliable, the first transfer surface P1 may be greater than each of the first and second coverage surfaces V1, V2, providing a larger bonding surface and thus improving adhesion.

The coverage z1, Z2, Z3 and transfer R1, R2 widths are preferably less than 10 mm and even more preferably less than 3 mm and most preferably less than 1.5 mm.

### Short Circuit Currents and Active Surface Areas

The front face short circuit current of a photovoltaic cell is defined as the maximum current generated by said photovoltaic cell when its front face is oriented towards an illumination source and its back face is masked. The short circuit currents on the front face of the end shingles 1, 2 and intermediate shingles 3′, 3″ determine the maximum current that can be produced by the photovoltaic string 101 with the front face of each shingle 1, 2, 3′, 3″ exposed to an illumination source 50. The end shingles 1, 2 and intermediate shingles 3′, 3″ are electrically connected in series. Therefore, the maximum current of the photovoltaic string 101 is limited by the lowest current producing shingle.

The short circuit current depends on several factors such as the conversion efficiency of the photovoltaic cell or the surface exposed to the illumination source, which is called the active surface area. The larger the active surface area, the greater the short circuit current. The first and second end shingles 1, 2 and the first and second intermediate shingles 3′, 3″ have first, second, third and fourth active surface areas Sa1, Sa2, Sa3′, Sa3″ respectively on their front faces. The first, second, third and fourth active surface areas Sa1, Sa2, Sa3′, Sa3″ occupy only a portion of each front face, reduced by the transfer surfaces P1 and coverage surfaces V1, V2, V3.

The first active surface area Sa1 extends on the front face of the first end shingle 1, over the entire length W of the shingle 1 and over a first exposed width A1. When the first transfer surface P1 extends over the entire length of the first end shingle 1, the first exposed width A1 is equal to the width of the first end shingle L1 minus the first transfer width R1. Similarly:
the second active surface area Sa2 extends on the front face of the second end shingle 2, over the entire length W of the shingle 2 and over a second exposed width A2 equal to L2−Z2.
the third active surface area Sa3′ extends on the front face of the first intermediate shingle 3′, over the entire length W of the shingle 3′ and over a third exposed width A3′ equal to L3′−Z1
the fourth active surface area Sa3″ extends on the front face of the second intermediate shingle 3″, over the entire length W of the shingle 3″ and over a third exposed width A3″ equal to L3″−Z3.

With respect to the coverage surfaces V1, V2, V3 of the other shingles 2, 3′, 3″, the first active surface area Sa1 is reduced with respect to the other active surface areas Sa2, Sa3′, Sa3″ by a surface area equal to P1−max(V1, V2, V3). The short circuit current of the first end shingle 1 is thus lower than the short circuit currents of the other shingles 2, 3′, 3″, thus limiting the maximum current of the photovoltaic string 101.

The invention provides three technical solutions to prevent the first end shingle 1 from limiting the maximum current of the photovoltaic string. The three technical solutions increase the short circuit current on the front face of the first end shingle 1 when the first transfer surface P1 is masked so that it is greater than or equal to the lowest of the short circuit currents on the front face of the intermediate shingles 3′, 3″ when their coverage surfaces V1, V3 are masked. In this way, one of the intermediate shingles 3′, 3″ becomes the shingle limiting the maximum current of the photovoltaic string 101. This may be the first intermediate shingle 3′, the second intermediate shingle 3″ or another intermediate shingle. Since the intermediate shingles 3′, 3″ are preferably selected to generate substantially equal short circuit currents on the front face, that is, to within 5%, the current generated by the photovoltaic string 101 is nominal.

To this end, according to a first alternative, it is provided that the short circuit current on the front face of the first end shingle 1, when the front face is fully exposed to the radiation source 50, is greater than the short circuit current on the front face of an intermediate shingle 3′, 3″ when its front face is fully exposed to the radiation source 50. The first end shingle 1 may have a higher photoelectric conversion efficiency than the intermediate shingle 3′, 3″, compensating for example for the reduction of the first active surface area Sa1 relative to the third and fourth surfaces Sa3′, Sa3″. In this way, when the first transfer surface P1 is masked by the first metal connector 31, the first end shingle 1 does not limit the maximum current of the photovoltaic string 101.

In order to keep the same conversion efficiencies for all the shingles 1, 2, 3′, 3″, a second alternative embodiment of the photovoltaic string 101 provides that the active surface area Sa1 on the front face of the first end shingle 1 is greater than or equal to the active surface area Sa3′, Sa3″ on the front face of the intermediate shingle 3′, 3″. In this way, with an equal conversion efficiency, the short circuit current on the front face generated by the first end shingle 1 is at least equal to the current generated by the intermediate shingle 3′, 3″.

In order to increase the first active surface area Sa1, the width L1 of the first end shingle 1 may be greater than the width L3′, L3″ of the intermediate shingle 3′, 3″. For example, if the transfer width R1 is fixed, then increasing the width L1 of the first shingle increases the exposed width A1. Thus, if all shingles 1, 2, 3′, 3″ have the same length W, then the active surface area Sa1 is greater than or equal to the active surface area Sa3′, Sa3″ on the front face of the intermediate shingle 3′, 3″. Shingles with identical lengths W facilitate the integration of the photovoltaic string, which is why it is preferable to vary the width of the shingles. For example, the coverage widths Z1, Z2, Z3 can be equal to 0.5 mm for shingles with widths L2, L3′, L3″ of 26 mm and the first transfer width R1 can be equal to 0.9 mm for a first end shingle with width L1 equal to 31.2 mm.

### Discontinuous Metal Connector

In order to increase the active surface area Sa1 of the front face of the first end shingle 1, the length W′ of the first transfer surface P1 can be reduced while keeping the first transfer width R1 identical. For this purpose, the first metal connector 31 extends along the covered edge of the first end shingle 1 over a length W′, as illustrated in FIG. 1. For example, the length W′ of the first transfer surface P1 may be equal to W/2.

Reducing the length W′ of the first transfer surface P1 may also allow for an increase in the first transfer width R1 to improve the reliability of the connection. For example, the length W′ may be less than W/2 and the first transfer width R1 may be greater than Z1 and less than twice Z1. Thus, the first transfer width R1 is increased, making the connection more reliable, while reducing the first transfer area P1. The first active surface area Sa1 is thus increased.

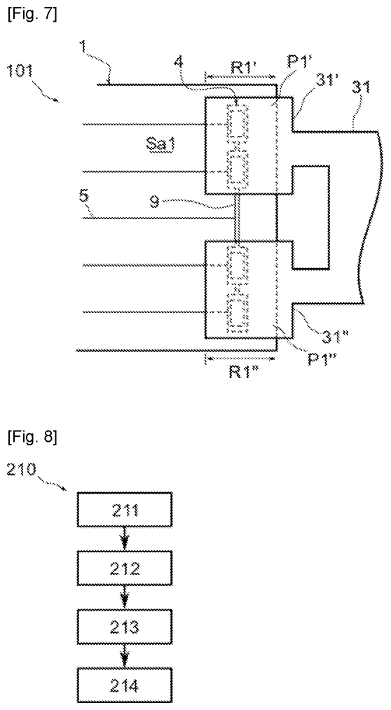

In order to provide a larger first active surface area Sa1, one embodiment of the photovoltaic string 101, illustrated in FIG. 7, provides that the first metal connector 31 comprises a plurality of disjointed portions 31′, 31″. Each portion of the first metal connector 31′, 31″ is connected to the front face of the first end shingle 1, covering a portion of the first transfer surface P1′, P1″. Each portion of the first transfer surface P1′, P1″ has a transfer width R1′, R1″, with both transfer widths R1′, R1″ preferably being equal to R1. In this way, the transfer widths R1′, R1″ can be increased while reducing the surface area covered with the portions of the first transfer surface P1′, P1″. The transfer widths R1′, R1″ can be greater than each of the first and second coverage widths Z1, Z2, making the connection more reliable while increasing the first active surface area Sa1.

Each disjointed portion 31′, 31″ of the first metal connector 31 also has a restricted width relative to the width W of the first end shingle 1. Thus, upon thermal expansion of the photovoltaic string 101, as the coverage widths between copper and silicon are reduced, differential thermal expansion, also known as the bimetal effect, is limited. Thus, the camber of the photovoltaic string 101 is limited.

The first metal connector 31 comprises, for example, six disjointed portions 31′, 31″ each having a length of 11 mm, occupying a total length W′ of 66 mm with respect to the 156 mm of the first shingle 1, that is, approximately 42% of 156 mm. Alternatively, the first metal connector 31 may comprise twelve disjointed portions 31′, 31″ each having a length of 5 mm, occupying a total length W′ of 60 mm, or about 38% of 156 mm.

The shading caused by the metallisations running along the front face between the portions 31′, 31″ of the first metal connector 31 is advantageously taken into account in the calculation of the first active surface area Sa1. The interconnection conductor track 4 is preferably located in the first transfer surface. In the case where the first metal connector 31 comprises several disjointed portions 31′, 31″, the interconnection track 4 preferably extends in each portion of the first transfer surface P1′, P1″. However, the conductor line 9, connecting conductive elements of the interconnection track 4, may extend outside the portions of the first transfer surface P1′, P1″ thus creating additional shading to be taken into account in the calculation of the first active surface area Sa1. Similarly, one or more collection fingers connected to the conductor line 9 extend outside the portions of the first transfer surface P1′, P1″. They also create additional shading to be taken into account in the calculation of the first active surface area Sa1.

### Shingle Distribution

The photovoltaic string 101 has, for example, a length in the order of one meter. The photovoltaic string 101 may then comprise thirty-six shingles having a width of 26 mm or thirty shingles having a width of 31.2 mm. The 26 mm shingles are, for example, obtained by cutting a 156 mm by 156 mm substrate into six portions and the 31.2 mm shingles are obtained by cutting the 156 mm by 156 mm substrate into five portions. It is also contemplatable to cut shingles with a width of, for example, 27 mm. The latter shingle can be obtained by cutting the 156 mm by 156 mm substrate into five portions, however generating an offcut of 21 mm.

The advantage of a shingle having a width of 31.2 mm is that it avoids generating offcut during cutting. The disadvantage is to increase the total length of the photovoltaic string 101 without increasing the maximum current generated because it is limited by one of the intermediate shingles 3′, 3″. In an example embodiment, the photovoltaic string 101 may comprise thirty-five 26 mm wide shingles and a first 27 mm wide end shingle 1.

Whether using a 27 mm wide shingle or a 31.2 mm wide shingle to form the photovoltaic string 101, in both cases it is necessary to have substrates having different metallisations, a first batch consisting of substrates dedicated to cutting 26 mm shingles and a second batch consisting of substrates dedicated to cutting 27 mm or 31.2 mm shingles.

In order to optimize the use of the substrates by providing only one type of substrate, each substrate can have two types of metallisation allowing five 25.9 mm shingles and one 26.5 mm shingle to be cut. Thus, the photovoltaic string 101 can comprise thirty 25.9 mm wide shingles and six 26.5 mm wide shingles, of which at least one 26.5 mm wide shingle is disposed in place of the first end shingle 1. The remaining five 26.5 mm shingles act as intermediate shingles and are distributed within the photovoltaic string 101. Each 26.5 mm intermediate shingle has a greater active surface area than each of the active surface areas of the 25.9 mm intermediate shingles, thus the 26.5 mm intermediate shingles do not limit the maximum current of the photovoltaic string 101.

More generally, the photovoltaic string 101 may comprise, in addition to the first end shingle, one or more intermediate shingles of greater width (and thus greater active surface area) than the other intermediate shingles, in order to optimize the use of the photovoltaic cell substrates (that is, full size photovoltaic cells).

### Bifacial Shingles

The end and intermediate shingles 1, 2, 3′, 3″ may be bifacial, that is, their front and back faces are capable of capturing electromagnetic radiation 50 to transform it into electric current. The short circuit current on the back face of a photovoltaic cell is defined as the maximum current generated by said photovoltaic cell when its back face is oriented towards an illumination source and its front face is masked. Thus, the maximum current of the photovoltaic string 101 comprising bifacial shingles 1, 2, 3′, 3″ is determined by short circuit current on the front face and the back face of each shingle 1, 2, 3′, 3″.

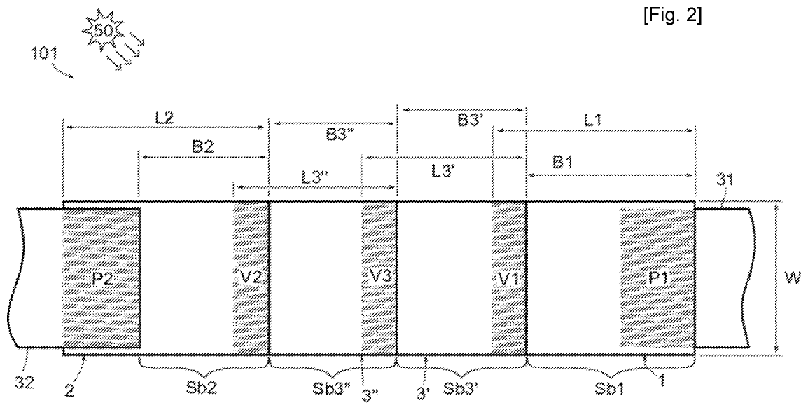

In a second embodiment illustrated in FIG. 2, the end and intermediate shingles 1, 2, 3′, 3″ comprise fifth, sixth, seventh and eighth active surface areas Sb1, Sb2, Sb3′, Sb3″, respectively, on their back faces. The fifth, sixth, seventh and eighth active surface areas Sb1, Sb2, Sb3′, Sb3″ occupy only a portion of each back face, reduced by the second transfer surface P2 and the coverage surfaces V1, V2, V3:
the fifth active surface area Sb1 extends on the back face of the first end shingle 1, over the entire length W of the shingle 1 and over a fifth exposed width B1. The fifth exposed width B1 is equal to the width L1 of the first end shingle 1 minus the first coverage width Z1,
the sixth active surface area Sb2 extends on the back face of the second end shingle 2, over the entire length W of the shingle 2 and over a sixth exposed width B2 equal to L2−R2.
the seventh active surface area Sb3′ extends on the back face of the first intermediate shingle 3′, over the entire length W of the shingle 3′ and over a seventh exposed width B3′ equal to L3′−Z3.
the eighth active surface area Sa3″ extends on the back face of the second intermediate shingle 3″, over the entire length W of the shingle 3″ and over an eighth exposed width B3″ equal to L3″−Z2.

In order that the maximum current of the photovoltaic string 101 is not limited by the second end shingle 2, the short circuit current on the back face of the second end shingle 2 when the second transfer surface P2 is masked is advantageously greater than or equal to the short circuit current on the back face of an intermediate shingle 3′, 3″ when its coverage surface is masked. The intermediate shingle 3′, 3″ thus becomes the shingle limiting the current of the photovoltaic string 101. The limiting shingle may be the first intermediate shingle 3′, the second intermediate shingle 3″ or another intermediate shingle.

An alternative embodiment of the photovoltaic string 101 provides that the width L2 of the second end shingle 2 is greater than the width L3′, L3″ of the intermediate shingle 3′, 3″. In this way, the sixth exposed length B2 is increased and the active surface area Sb2 of the back face of the second end shingle 2 is greater than or equal to the active surface area Sb3′, Sb3″ of the back face of the intermediate shingle 3′, 3″. In this way, the second end shingle 2 does not limit the maximum current of the photovoltaic string 101 when the shingles 1, 2, 3′, 3″ are bifacial.

### Interconnection Conductor Track for Bonding

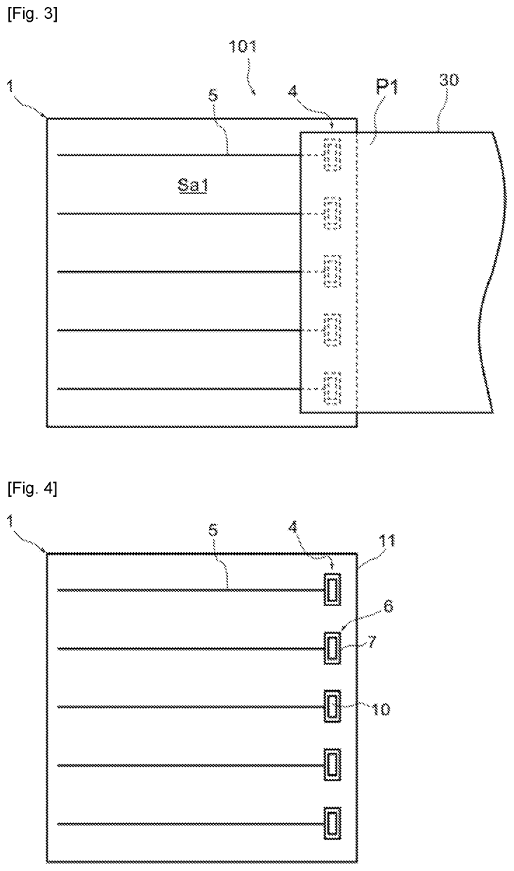

FIGS. 3 to 6 schematically represent several embodiments of the photovoltaic string 101 and more particularly different ways of bonding the first metal connector 31 to the first interconnection shingle 1. However, the teachings set out below are transposable to the second interconnection shingle 2 and to the second metal connector 32. In this case:
by “first end shingle 1”, it should be read “second end shingle 2”
by “front face”, it should be read “back face”
by “first metal connector 31” it should be read “second metal connector 32”.

In the embodiment of FIG. 3, referring also to FIG. 4, the interconnection track 4 of the front face of the first end shingle 1 comprises a plurality of spaced-apart closed-contour conductor patterns 6, each closed-contour conductor pattern 6 comprising a closed contour 7 surrounding a portion of the front face 10.

The closed-contour conductor patterns 6 belonging to the interconnection conductor track 4 of the front face of the first end shingle 1 are intended to accommodate portions of the second electrically conductive adhesive for bonding the first metal connector 31 to the first end shingle 1. The closed contours 7 allow the second electrically conductive adhesive to be retained and located when the first metal connector 31 is pressed, during the manufacture of the photovoltaic string 101, against the front face of the first end shingle 1.

At least some of the closed-contour conductor patterns 6 each contain a portion of the second electrically conductive adhesive adhering to the portion of the front face 10 and the first metal connector 31. For each portion of the second electrically conductive adhesive, a first part of the second electrically conductive adhesive is in contact with the metallised closed contour 7, while a second part of the second electrically conductive adhesive 7 is directly in contact with the substrate. Because the second electrically conductive adhesive has two to three times the adhesion to the substrate, the adhesion level of the connection of the first metal connector 31 is thus improved. Additionally, each portion of the second electrically conductive adhesive retained by the closed contour 7 is in contact with said closed contour 7 thus making electrical contact.

Preferably, each of the closed-contour conductor patterns 6 contains a portion of the second electrically conductive adhesive, thereby providing improved adhesion and electrical connection.

The spacing between the closed-contour conductor patterns 6 has the effect of reducing the amount of conductive paste required to make the interconnection conductor track 4.

The interconnection conductor track 4 preferably extends into the first transfer surface P1. Since each closed-contour conductor pattern 6 participates in the connection of the first metal connector 31, the closed-contour conductor patterns 6 are advantageously located in the first transfer surface P1 or are advantageously located in the portions of the first transfer surface P1′, P1″.

Preferably, one or more closed-contour conductor patterns 6 are electrically connected to one or more collection fingers 5 each. For example, each closed-contour conductor pattern 6 may be electrically connected to one collection finger 5. Preferably, the electrical connection is made by a direct connection of each conductor pattern 6 to the collection finger 5. When the closed-contour conductor patterns 6 each comprise a conductor pad 8, the collection finger 5 is preferably connected to each closed-contour conductor pattern 6 as an extension of the conductor pad 8.

### Closed Contour

FIG. 5 schematically sets forth the interconnection conductor track 4 of the front face of the first end shingle 1. FIG. 5 is especially enlarged on two closed-contour conductor patterns 6. Each closed contour 7 may have a rectangular shape formed by four contiguous retention lines, connected to each other and disposed facing each other in pairs. The retention lines are advantageously disposed perpendicularly or in parallel to the edge 11. Therefore, the lines preferably disposed in parallel or perpendicular to the edge 11 will be referred to as “retention lines parallel to the edge 11” or “retention lines perpendicular to the edge 11”. The rectangular shape of the closed contours 7 makes it easy to optimize the width of the closed-contour conductor patterns 6 while keeping a surface area portion of the first face 10 constant.

Each closed contour 7 has an outer width D, measured perpendicular to the edge 11 and an outer length G, measured in parallel to the edge 11. The outer width and length D, G are preferably identical for all closed contours 7 of the interconnection track 4. In order to limit the first transfer width R1, the outer width D is preferably between 400 μm and 1100 μm. Thus, the first transfer width R1 can be between 0.8 mm and 1.5 mm. Since the closed contours 7 are disposed within the first transfer zone P1, the outer length G may be greater than the outer width, in order to optimize the portion of the front surface in contact with the second electrically conductive adhesive. For example, the outer length G may be between 700 μm and 2000 μm.

Each closed contour 7 also has an inner width C, measured perpendicular to edge 11, and an inner length F, measured in parallel to edge 11. The inner width C, F and length are preferably identical for all closed contours 7 of the interconnection track 4. The inner width C is preferably between 200 μm and 1000 μm. The inner length F is preferably between 500 μm and 1900 μm. The surface area of the portion of the front face 10 is equal to the product of the inner width C and the inner length F, and is preferably between 0.1 mm² and 2.9 mm².

The width Q of the retention lines parallel to the edge 11, is preferably less than twice the width N of a collection finger 5. The retention lines parallel to the edge 11 need not be very wide since it scarcely contributes to mechanical adhesion. The primary role of the retention lines parallel to the edge 11 is to limit creep of the second electrically conductive adhesive in a direction perpendicular to the edge 11. Thus, making retention lines parallel to the edge 11 narrow fora same outer width D of closed contours 7 increases the inner width C and thus the surface area of the portions of the front face 10 surrounded by the closed contours 7. When the width N of the collection fingers 5 is, for example, 50 μm, the retention lines parallel to the edge 11 advantageously have a width Q less than 100 μm. For example, for a first transfer width R1 equal to 0.9 mm, the retention lines each have a width Q equal to 60 μm.

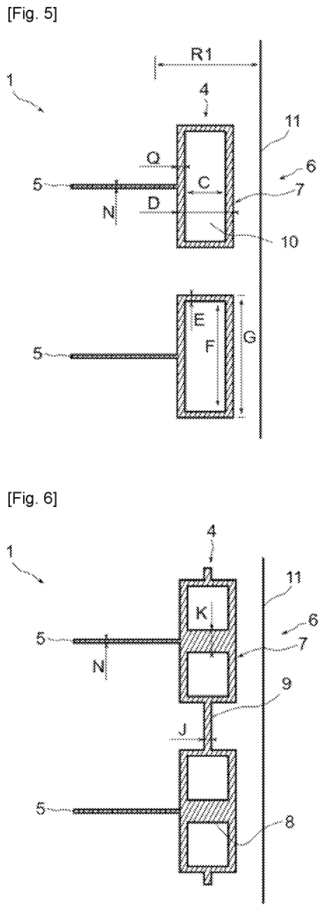

In the embodiment of FIG. 6, at least some of the conductor patterns 6 each comprise a conductor pad 8, located within the closed contour 7 and connected to the closed contour 7. Preferably, each of the conductor patterns 6 of the interconnection track 4 comprises a conductor pad 8. The conductor pad 8 enables resistive losses within the interconnection conductor track 4 to be reduced. During interconnection, the portion of the second electrically conductive adhesive which is deposited on the conductor pattern 6 is in contact with a portion of the closed contour 7. In the presence of the conductor pad 8, the surface of the conductor pad 8 is covered with the portion of the second adhesive thus making additional electrical contact.

The conductor pad 8 is preferably oriented perpendicular to the edge 11, passing through the portion of the front face 10 on either side. The conductor pad 8 thus divides the portion of the front face 10 into two sub portions of the front face. Preferably, the surface areas of the two sub portions of the front face are equal.

The conductor pad 8 has a width K, measured in parallel to the edge 11, greater than 1.5 times the width N of a collection finger 5. When the width N of a collection finger 5 is, for example, 50 μm, the conductor pad 8 has a width greater than 75 μm. However, in order to further reduce the resistive losses within the interconnection track 4, the conductor pad 8 may have a width K greater than or equal to twice the width N of a collection finger 5. For example, when the width n of a collection finger 5 is equal to 50 μm, the conductor pad 8 has a width K equal to 120 μm, or 2.4 times the width of a collection finger.

When a collection finger 5 is connected to a conductive pattern 6 as illustrated in FIG. 6, the conductor pad 8 is preferably located in the extension of the collection finger 5, in order to reduce the path taken by the electric current from the collection finger 5 to the portion of the second electrically conductive adhesive.

When the conductor pad 8 has a width K less than twice the width N of a collection finger 5, or when there is no conductor pad 8, the retention lines perpendicular to the edge 11 can advantageously have a width E, measured in parallel to the edge 11, greater than 1.5 times the width N of a collection finger 5. According to this configuration, said retention lines each have a surface area to increase adhesion and improve electrical conductivity, compensating for the absence of the conductor pad 8 or a narrow conductor pad 8. During interconnection of the first end shingle 1, moreover, care will be taken to cover said wide retention lines with a layer of the second electrically conductive adhesive in order to make electrical contact. Even more advantageously, the retention lines perpendicular to the edge 11 can have a width E equal to 2.4 times the width N of a collection finger 5, further improve the adhesion of said retention lines and the electrical conductivity. When the width N of the collection fingers 5 is for example 50 μm, the retention lines perpendicular to the edge 11 have a width greater than 100 μm, preferably equal to 120 μm.

When the conductor pad 8 has a width K equal to 2.4 times the width N of a collection finger 5, the retention lines perpendicular to the edge 11 advantageously have a width E less than or greater than twice the width N of a collection finger 5. In this way, said retention lines limit creep of the second adhesive in parallel to the edge 11 while increasing the surface area of the portion of the front face 10 surrounded by the closed contour 7. When the width N of the collection fingers is, for example, 50 μm, the retention lines perpendicular to the edge 11 can have a width E between 50 μm and 100 μm.

### Conductor Line

In the embodiment of FIG. 6, the interconnection conductor track 4 comprises a conductor line 9 electrically connecting two consecutive closed-contour conductor patterns 6. More particularly, the conductor line 9 connects the closed contour 7 of a first pattern 6 with the closed contour 7 of a second pattern 6.

Preferably, the conductor line 9 is a discontinuous line electrically connecting all the closed-contour conductor patterns 6 in pairs. It comprises several portions, each portion of the first conductor line 9 connecting two consecutive conductor patterns 6. By means of the conductor line 9, the interconnection conductor track 4 is continuous, facilitating the measurement of electrical characteristics I(V) of the first end shingle 1. In the case of a discontinuous interconnection track 4, it is necessary to use a specific so-called “busbarless” device connecting each conductor pattern 6.

In order to limit the number of closed-contour conductor patterns 6 and thus reduce the amount of conductive paste required to manufacture them, the conductor line 9 is advantageously connected to one or more collection fingers 5. In this way it is possible to connect collecting fingers 5 without increasing the number of conductor patterns 6. The electric current from a collection finger 5 flows to the nearest conductor patterns 6 via the conductor line 9.

The closed-contour conductor patterns 6 of the interconnection conductor track 4 are preferably disposed within the first portions of the transfer surface P1′, P1″ to reduce masking of the active face Sa1. A part of the conductor line 9 may extend outside the transfer surfaces P1′, P1″, allowing the connection of at least one collection finger 5 while limiting masking on the first active surface area Sa1.

### Method for Manufacturing the Bonded Photovoltaic String

FIG. 8 schematically represents a method for manufacturing a photovoltaic string 210 according to a second aspect of the invention. The method 210 enables the photovoltaic string 101 to be manufactured according to the first aspect of the invention.

The method 210 comprises a step of providing 211:
the first end shingle 1;
the second end shingle 2;
the first and second intermediate shingles 3′, 3″; and
the first metal connector 31.

The providing step 211 may itself comprise the steps of manufacturing the end shingles 1, 2 and the intermediate shingles 3′, 3″ from a semiconductor substrate. As an example, the end shingles 1, 2 and the intermediate shingles 3′, 3″ may be derived from a larger photovoltaic cell, called a full-size photovoltaic cell or full plate, for example 156 mm by 156 mm, cut into at least 4 portions, for example 5 portions of 31.5 mm by 156 mm or even 6 portions of 26 mm by 156 mm or of different lengths.

The providing step 211 may comprise screen-printing conductive elements on each of the faces of the end shingles 1, 2 and intermediate shingles 3′, 3″, especially comprising the interconnection conductor tracks 4 and the collection fingers 5. The conductive elements have a metal character and are screen-printed from a conductive paste containing metal particles, for example silver. The conductive paste has a crosslinking temperature of less than 250° C. providing the electrical conduction and mechanical adhesion properties.

When the screen-printing of the interconnection conductor track 4 uses a screen-printing screen with the direction of the component wires parallel to the collection fingers 5, also known as 0° screen-printing or knotless printing, it is not possible to screen-print elements perpendicular to the collection fingers 5. On the other hand, the shape of a broken line can be achieved with this technology. Thus, when knotless screen-printing is implemented for screen-printing the interconnection conductor track 4, care will be taken to screen-print a line having a broken (or zig-zag) line shape, comprising short segments, in the order of 100 μm long, tilted at an angle α with respect to the edge 11 comprised between 10° and 30° and preferably between 10° and 15°.

The method 210 comprises a first step 212 of interconnecting the first end shingle 1 to the first intermediate shingle 3′. For this, at least a first portion of the first electrically conductive adhesive is deposited on the front face of the first intermediate shingle 3′ and preferably on the interconnection conductor track 4 of the first intermediate shingle 3′. Advantageously, the first portion of the first electrically conductive adhesive is deposited over the entire length of the interconnection conductor track 4. When a plurality of first portions of the first electrically conductive adhesive are involved, the first portions of the first adhesive are evenly distributed over the entire length of the interconnection conductor track. In this way, the adhesion is evenly distributed between the interconnection conductor track 4 and the first end shingle 1. When the interconnection conductor track 4 of the first intermediate shingle 3′ comprises a plurality of closed-contour conductor patterns 6, the first portions of the first electrically conductive adhesive are advantageously deposited on at least some of said closed-contour conductor patterns 6 and preferably on all the closed-contour conductor patterns 6. The first electrically conductive adhesive is preferably deposited by screen-printing, ink jet printing or dispensing.

The back face of the first end shingle 1 is pressed against the first portion or portions of the first electrically conductive adhesive to make mechanical and electrical contact. Advantageously, when the back face of the first end shingle 1 comprises an interconnection conductor track 4, the interconnection conductor track 4 is placed facing the interconnection conductor track 4 of the front face of the first intermediate shingle 3′ and pressed against the first portion or portions of the first electrically conductive adhesive, thus ensuring good electrical contact. When the interconnection conductor track 4 of the back face of the first end shingle 1 also comprises a plurality of closed-contour conductor patterns 6, the closed-contour conductor patterns 6 of the front face of the first intermediate shingle 3′ are advantageously aligned with the closed-contour conductor patterns 6 of the back face of the first end shingle 1, thus ensuring good mechanical contact. During the first interconnection step 212, the back face of the first end shingle 1 covers the first coverage surface V1 of the front face of the first intermediate shingle 3′, the first coverage surface V1 extending from the covered edge of the front face of the first intermediate shingle 3′ over a first coverage width Z1.

The method 210 comprises a second step 213 of interconnecting the second intermediate shingle 3″ with the second end shingle 2 accomplished in the same manner as the first interconnection step 212. At least a second portion of the first electrically conductive adhesive is deposited on the front face of the second end shingle 2 and preferably on the interconnection conductor track 4 and even more preferably on at least some of the closed-contour conductor patterns 6 when the interconnection conductor track 4 includes them.

The back face of the second intermediate shingle 3″ is pressed against the second portion or portions of the first electrically conductive adhesive. The back face of the second intermediate shingle 3″ covers the second coverage surface V2 of the front face of the second end shingle 2, the second coverage surface V2 extending from the covered edge of the front face of the second intermediate shingle 3″ over a second coverage width Z2.

The method 210 comprises a third step of connecting 214 the first metal connector 31 to the first end shingle 1. For this, at least a third portion of the second electrically conductive adhesive is disposed on the first metal connector 31. The nature of the second electrically conductive adhesive, if different from the first electrically conductive adhesive implemented in the preceding steps, is preferably compatible with the nature of the first metal connector 31. For example, the first connector 31 may be covered with a tin-lead alloy that may oxidize upon contact with certain electrically conductive adhesives. Advantageously, the third portion of the second electrically conductive adhesive is deposited over the entire width W′ of the first metal connector 31, even when the interconnection conductor track 4 on the front face of the first end shingle 1 comprises a plurality of closed-contour conductor patterns 6. In this way, the adhesion is evenly distributed on the interconnection conductor track 4 on the front face of the first end shingle 1.

The first metal connector 31 is pressed against the front face of the first end shingle 1 so that the third portion of the second electrically conductive adhesive is pressed against the front face of the first end shingle 1. In this manner, mechanical and electrical contact is made between the first end shingle 1 and the first metal connector 31. The first metal connector 31 covers the first transfer surface P1 of the front face of the first end shingle 1. The first transfer surface P1 extends from the covered edge of the front face of the first end shingle 1 over the first transfer width R1. In order to ensure the reliability of the photovoltaic string 101 thus produced, care will be taken to ensure that the first transfer width R1 is greater than each of the first and second coverage widths Z1, Z2.

Preferably, care will also be taken that the first transfer surface P1 is greater than each of the first and second coverage surfaces V1, V2.

The photovoltaic string 101 undergoes thermal treatment for a few seconds to a few minutes at a temperature of between 120° C. and 160° C. to crosslink the portions of the first and second electrically conductive adhesives.

### Welded Photovoltaic String

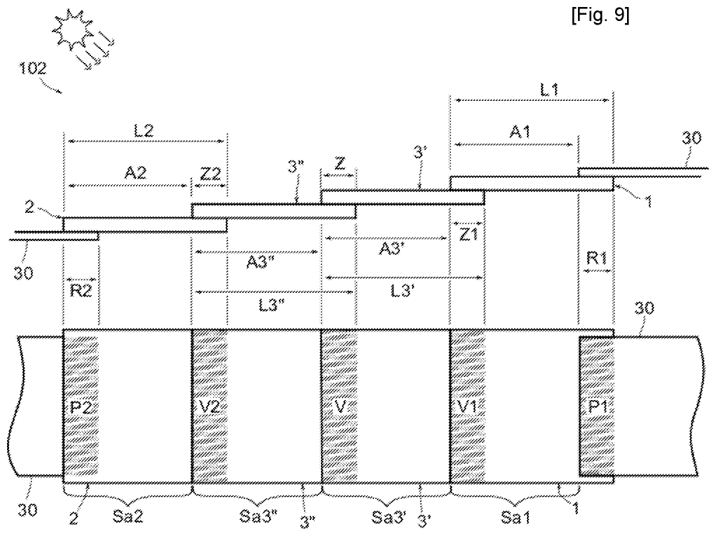

FIG. 9 schematically represents a photovoltaic string 102 according to a third aspect of the invention. It largely comprises the characteristics of the photovoltaic string 101 according to the first aspect of the invention (illustrated in FIG. 1).

The difference with the photovoltaic string 101 according to the first aspect of the invention lies in the technology for connecting the first and second metal connectors 31, 32 to, respectively, the first and second end shingles 1, 2. According to the first aspect of the invention, the connections of the first and second metal connectors 31, 32 are made by means of the second electrically conductive adhesive, allowing the same connection technology to be kept throughout the photovoltaic string 101. According to the second aspect of the invention, the connections of the first and second metal connectors 31, 32 are made by directly welding the first and second connectors 31, 32 to each of the first and second end shingles 1, 2, respectively. The first metal connector 31 is welded to the first end shingle 1 and preferably welded to the interconnection conductor track 4 on the front face of the first end shingle 1. The first metal connector 31 covers the first transfer surface P1 of the front face of the first end shingle 1, extending on the first transfer width R1 from the covered edge of the first end shingle 1. The second metal connector 32 is welded to the second end shingle 2 and preferably welded to the interconnection conductor track 4 or the metallisation of the back face of the second end shingle 2. The second metal connector 32 covers the second transfer surfaces P2 of the back face of the second end shingle 2, extending on the second transfer width R2 from the covered edge of the second end shingle 2. Welding metallised surfaces, such as for example the first and second metal connectors 31, 32, has the advantage of providing better adhesion than bonding metallised surfaces with the second electrically conductive adhesive.

Welding thus makes it possible to limit the first and second transfer widths R1, R2 with respect to the connections by means of the second adhesive while making the connections within the photovoltaic string 102 more reliable. Preferably, a first transfer width R1 is chosen to be less than or equal to the largest of the first, second and third coverage widths Z1, Z2, Z3 and additionally substantially equal to the smallest of the coverage widths Z1, Z2, Z3. Thus, the first active surface area Sa1 of the first end shingle 1 is not reduced relative to the second, third and fourth active surface areas Sa2, Sa3′, Sa3″ and the first end shingle 1 does not limit the maximum current of the photovoltaic string 102.

When the shingles 1, 2, 3′, 3″ are bifacial, that is, when the back faces are capable of capturing electromagnetic radiation to transform it into current, a second transfer width R2 is preferably chosen to be less than or equal to the largest of the first, second, and third coverage widths Z1, Z2, Z3, and even more preferably substantially equal to the smallest of the coverage widths, Z1, Z2, Z3. Thus, the fifth active surface area Sb1 of the first end shingle 1 is not reduced relative to the sixth, seventh and eighth active surface areas Sb2, Sb3′, Sb3″ and the second end shingle 2 does not limit the maximum current of the photovoltaic string 102.

Even more preferably, the first and second transfer surfaces P1, P2 are each less than or equal to the largest of the first, second and third coverage surfaces V1, V2, V3.

The disjointed portions 31′, 31″ of the first metal connector 31 allow for an increase in the first active surface area Sa1 of the first end shingle 1 by reducing the surface area covered with the portions of the first transfer surface P1′ and P1″. In order that the first end shingle 1 does not limit the current of the photovoltaic string 102, the transfer length and width of each of the disjointed portions 31′, 31″ may be chosen such that the first active surface area Sa1 is greater than or equal to the active surface area Sa3′, Sa3″ on the front face of one of the intermediate shingles 3′, 3″. For the same first active surface area Sa1, reducing the length of each disjointed portion 31′, 31″ makes it possible to increase the transfer widths R1′, R1″ of each disjointed portion 31′, 31″ such that it is greater than each of the first and second coverage widths Z1, Z2. In this way, the reliability of the connection is enhanced.

### Interconnection Conductor Track for Welding

Welding of the first and second connectors 31 requires the implementation of a filler alloy. The filler alloy, when melted, wets only the metallised zones, such as the interconnection conductor tracks 4 or the collection fingers 5. The interconnection conductor track 4 preferably extends into the first transfer surface P1 so as to be contacted by the filler alloy.

The interconnection conductor track 4 may be continuous and preferably does not have a closed-contour conductor pattern, thus providing a large metallised surface area to facilitate wetting of the filler alloy. The interconnection conductor track 4 may extend along the covered edge, over the entire length W of the edge. However, in order to limit differential thermal expansion, it is preferred that the first metal connector 31 comprise the plurality of disjointed portions 31′, 31″, each portion 31′, 31″ being welded to the interconnection conductor track 4.

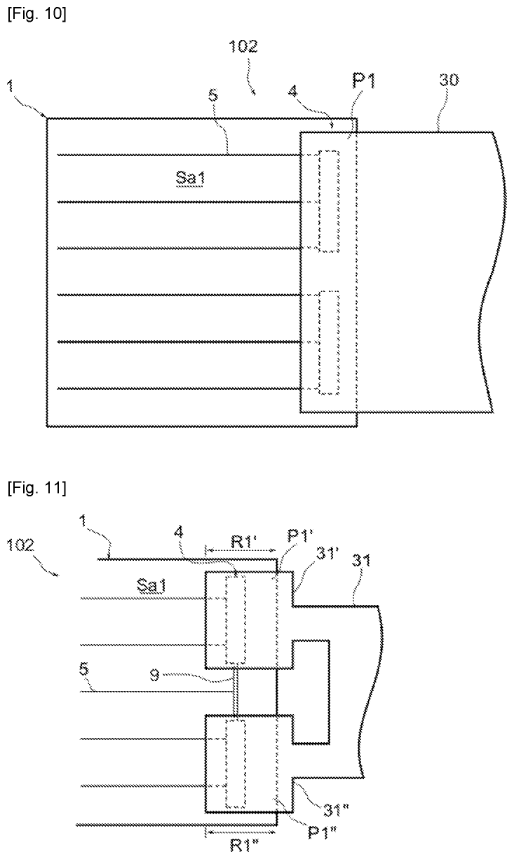

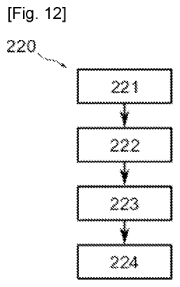

In the embodiment of FIG. 10, the interconnection conductor track 4 may comprise a plurality of discontinuous portions extending into the first transfer surface P1, in parallel to the covered edge of the first end shingle 1. Thus, even when the interconnection conductor track 4 is welded to the first metal connector 31, differential thermal expansion is reduced. For example, the interconnection conductor track 4 may have six 24.5 mm wide discontinuous portions or fifteen 10 mm wide discontinuous portions. Differential expansion may be further reduced when the first metal connector 31 comprises the plurality of disjointed portions 31′, 31″. Preferably, the disjointed portions of the first metal connector 31′, 31″ each connect at least one of the discontinuous portions of the interconnection track 4, as illustrated in FIG. 11. For example, the first metal connector 31 may comprise six 11 mm long disjointed portions 31′, 31″, spaced 17.5 mm apart, or twelve 5 mm long disjointed portions 31′, 31″, spaced 8.5 mm apart.

In the embodiment of FIG. 11, the interconnection conductor track 4 comprises the conductor line 9 electrically connecting two consecutive discontinuous portions of the interconnection conductor track 4. The conductor line 9 also electrically connects a collection finger located outside the portions of the first transfer surface P1′, P1″. Preferably, the interconnection conductor track 4 comprises a plurality of portions electrically connecting all discontinuous portions of the interconnection conductor track 4. Thus, the interconnection conductor track is continuous, facilitating the measurement of electrical characteristics I(V) of the first end shingle 1. In the case of a discontinuous interconnection track 4, it is necessary to use a specific so-called “busbarless” device.

### Double Printing

Two types of conductive paste are used to screen-print the conductive elements on the front face of the first end shingle 1. The so-called high temperature conductive pastes, are mainly used on homojunction type substrates. So-called high-temperature conductive pastes are heated to a temperature above 700° C., allowing the melting of a glass phase for adhesion. So-called low temperature conductive pastes are mainly used on heterojunction type substrates. Low temperature conductive pastes have a crosslinking temperature in the order of 250° C. They do not contain a glass phase and adhesion is obtained by the resin contained in the paste.

In order to obtain a welding joint of the first metal connector 31 having a good tear resistance for a homojunction substrate, the high-temperature conductive paste for producing the interconnection conductor track 4 will advantageously have a high silver content, greater than 70% and preferably greater than 80%.

In order to obtain a welding joint of the first metal connector 31 having a good tear resistance fora heterojunction substrate, the interconnection conductor track 4, made from a low-temperature conductive paste, will have a height greater than 15 μm and preferably greater than or equal to 25 μm.

### Bonding/Welding

A certain type of electrically conductive adhesive is loaded with metal so-called fusible particles, that is capable of melting. For example, this is a resin or polymer comprising tin-lead alloy particles. This type of electrically conductive adhesive has good adhesion to the substrate and can be heated to weld metal surfaces. In order to achieve welding with good tear resistance, it is necessary to have sufficiently large metallised surfaces. The interconnection conductor track 4 may for example comprise twelve disjointed portions of size 0.3 mm by 11.5 mm on which welding is performed, the twelve portions being spaced 1.5 mm apart within which the electrically conductive adhesive will adhere.

### Method for Manufacturing the Welded Photovoltaic String

FIG. 12 schematically represents a method for manufacturing 220 a photovoltaic string according to a fourth aspect of the invention. The method 220 enables the photovoltaic string 102 to be manufactured according to the third aspect of the invention.

This method 220 comprises the same steps as the manufacturing method 210 according to the second aspect of the invention except for the step of connecting 214 the first metal connector 31 to the first end shingle 1. According to the second aspect of the invention, the connection is made by means of a third portion of the second electrically conductive adhesive. The connection of the first connector 31 to the first end shingle 1 according to the fourth aspect of the invention is performed by a welding step 224.

In the welding step 224, the first connector element 31 is covered with a fusible alloy that will act as a filler metal. The fusible alloy is typically a tin-lead alloy or a tin-lead-silver alloy. The first metal connector 31 is contacted with the front face of the first end shingle 1, covering the first transfer surface P1, and the assembly is then heated to a temperature in the order of 200° C., melting the fusible alloy. During cooling, the fusible alloy solidifies, making the electrical and mechanical connection with the first end shingle 1. Preferably the first metal connector 31 is contacted with the interconnection conductor track 4 of the front face of the first end shingle 1. Indeed, when the fusible alloy is melted, it only wets on metallised elements such as the interconnection conductor track 4. In order not to degrade the first electrically conductive adhesive disposed within the other interconnections, localised heating will be preferred, for example by means of a thermal probe, also called a thermode.

In order to avoid the use of localised heating equipment such as a thermode, a first alternative of the welding step 224 provides for the use of a so-called low temperature fusible alloy, comprising a tin-bismuth-silver alloy with a melting temperature in the order of 150° C., corresponding to the crosslinking temperature of the first electrically conductive adhesive.

A second alternative of the welding step 224 provides for the use of a welding paste deposited on the interconnection conductor track 4. The welding paste is deposited on the first metal connector 31, advantageously over the entire width W′ of the first metal connector 31. In this way, the adhesion is evenly distributed on the interconnection conductor track 4 of the first end shingle 1. In a second step, the first metal connector 31 is pressed against the front face of the first end shingle 1 and especially against the interconnection conductor track 4. The welding paste is heated locally in order to melt the welding paste and perform the welding.

During the step of providing 211 the end and intermediate shingles according to the fourth aspect of the invention, the screen-printing of the conductive elements on the front face of the first end shingle 1, such as the interconnection conductor track 4 or the collection fingers, is advantageously carried out using a conductive paste formulated both to enable the collection fingers 5 and the interconnection conductor track 4 to be produced, for example for a heterojunction substrate, one of the Kyoto Elex™ conductive pastes L359™ or Q119™. However, two different conductive pastes will preferably be used to make the collection fingers 5 on the one hand, and the interconnection conductor track 4 on the other. The screen-printing of the collection fingers 5 and the interconnection conductor track 4 is made in two steps, also called dual print. The conductive paste for making the collection fingers 5, such as for example the Kyoto Elex™ conductive paste M931™, has a low resistivity and allows for the printing of narrow conductors, less than 50 μm. The conductive paste for making the interconnection conductor track 4, such as for example Kyoto Elex™ conductive paste R101™, has high adhesion and compatibility with the welding method.

In order to avoid dissolution of the silver contained in the collection fingers 5 during the welding step 224, the screen-printing of the conductive paste for making the interconnection conductor track 4 will slightly overlie each collection finger 5. This precaution is particularly interesting when the collection fingers 5 are made of a low temperature conductive paste, which is particularly disposed to silver dissolution. The screen-printing of the collection fingers 5 can be made in two steps to reduce their resistivity, also called dual print. Dual print allows the use of two different conductive pastes, each optimised for a specific function. Thus, during the first screen-printing, the collection fingers 5 and the interconnection track 4 are for example screen-printed from a conductive paste compatible with the welding method, such as Kyoto Elex™ conductive paste R103™. The second screen-printing increases the thickness of the interconnection conductor track 4, covering a part of each collection finger 5. For this, a low resistive conductive paste will be used, such as for example Kyoto Elex™ conductive paste M931™.

1. A photovoltaic string comprising:
a first photovoltaic cell forming a first end shingle;
a second photovoltaic cell forming a second end shingle;
a plurality of third photovoltaic cells forming intermediate shingles, disposed between the first and second end shingles; and
a first metallic connector;
each of the first, second and third photovoltaic cells comprising a front face and a back face opposite to the front face, the first end shingle, the intermediate shingles and the second end shingle being interconnected by a first electrically conductive adhesive, the first end shingle being interconnected to a first intermediate shingle, the back face of the first end shingle covering a surface of the front face of the first intermediate shingle, called a first coverage surface, the first coverage surface having a first coverage width, the second end shingle being interconnected to a second intermediate shingle, the back face of the second intermediate shingle covering a surface of the front face of the second end shingle, called a second coverage surface, the second coverage surface having a second coverage width, the first metallic connector being connected to the first end shingle by a second electrically conductive adhesive, the first metallic connector covering a surface of the front face of the first end shingle, called a first transfer surface, the first transfer surface having a first transfer width greater than each of the first and second coverage widths.

2. The photovoltaic string according to claim 1, wherein a short circuit current on the front face of the first end shingle when the first transfer surface is masked is greater than or equal to a short circuit current on the front face of an intermediate shingle when its coverage surface is masked.

3. The photovoltaic string according to claim 2, wherein the short circuit current on the front face of the first end shingle when its front face is fully exposed is greater than the short circuit current on the front face of the intermediate shingle when its front face is fully exposed.

4. The photovoltaic string according to claim 2, wherein an active surface area on the front face of the first end shingle is greater than or equal to an active surface area on the front face of the intermediate shingle.

5. The photovoltaic string according to claim 2, wherein a width of the first end shingle is greater than a width of the intermediate shingle.

6. The photovoltaic string according to claim 1, wherein the front face of the first end shingle comprises an interconnection conductor track extending into the first transfer surface, the interconnection conductor track comprising a plurality of spaced-apart closed-contour conductor patterns, each closed-contour conductor pattern comprising a closed contour surrounding a portion of the front face, at least some of the closed-contour conductor patterns each containing a portion of the second electrically conductive adhesive adhering to the portion of the front face and to the first metallic connector.

7. The photovoltaic string according to claim 6, wherein the interconnection conductor track comprises a conductor line electrically connecting two consecutive closed-contour conductor patterns.

8. The photovoltaic string according to claim 1, wherein the first metallic connector comprises a plurality of disjointed portions connected to the first end shingle, each portion of the first metallic connector covering a surface of the front face of the first end shingle, called a portion of the first transfer surface, each portion of the first transfer surface having a transfer width greater than each of the first and second coverage widths.

9. The photovoltaic string according to claim 1, further comprising:
a second metallic connector;
the second metallic connector being connected to the second end shingle by the second electrically conductive adhesive, the second metallic connector covering a surface of the back face of the second end shingle, called a second transfer surface, the second transfer surface having a second transfer width greater than each of the first and second coverage widths.

10. The photovoltaic string according to claim 9, wherein a short circuit current on the back face of the second end shingle when the second transfer surface is covered is greater than or equal to a short circuit current on the back face of an intermediate shingle when its coverage surface is masked.

11. A method for manufacturing a photovoltaic string comprising:
providing a first photovoltaic cell forming a first end shingle, a second photovoltaic cell forming a second end shingle, a plurality of third photovoltaic cells forming intermediate shingles and a first metallic connector, each of the first, second and third photovoltaic cells comprising a front face and a back face opposite to the front face;
interconnecting the first end shingle to a first intermediate shingle by a first electrically conductive adhesive, the back face of the first end shingle covering a surface of the front face of the first intermediate shingle, called the first coverage surface, the first coverage surface having a first coverage width;
interconnecting a second intermediate shingle to the second end shingle by the first electrically conductive adhesive, the back face of the second intermediate shingle covering a surface of the front face of the second end shingle, called the second coverage surface, the second coverage surface having a second coverage width;
connecting the first metallic connector to the first end shingle by a second electrically conductive adhesive, the first metallic connector covering a surface of the front face of the first end shingle, called the first transfer surface, the first transfer surface having a first transfer width greater than each of the first and second coverage widths.

12. A photovoltaic string comprising:
a first photovoltaic cell forming a first end shingle;
a second photovoltaic cell forming a second end shingle; and
a plurality of third photovoltaic cells forming intermediate shingles, disposed between the first and second end shingles; and
a first metallic connector;
each of the first, second and third photovoltaic cells comprising a front face and a back face opposite to the front face, the first end shingle, the intermediate shingles and the second end shingle being interconnected by a first electrically conductive adhesive, the first end shingle being interconnected to a first intermediate shingle, the back face of the first end shingle covering a surface of the front face of the first intermediate shingle, called the first coverage surface, the first coverage surface having a first coverage width, the second end shingle being interconnected to a second intermediate shingle, the back face of the second intermediate shingle covering a surface of the front face of the second end shingle, called the second coverage surface, the second coverage surface having a second coverage width, the first metallic connector being connected to the first end shingle the first metallic connector covering a surface of the front face of the first end shingle, called the first transfer surface, the first metallic connector being welded to the first end shingle, the active surface area on the front face of the first end shingle being greater than or equal to the active surface area on the front face of an intermediate shingle.

13. The photovoltaic string according to claim 12, wherein the front face of the first end shingle comprises an interconnection conductor track extending on the first transfer surface, the first metallic connector being welded to the interconnection conductor track.

14. The photovoltaic string according to claim 13, wherein the interconnection conductor track is continuous.

15. The photovoltaic string according to claim 14, wherein the interconnection conductor track comprises a plurality of disjointed portions, each portion being welded to the first metallic connector.

16. The photovoltaic string according to claim 15, wherein the interconnection conductor track comprises a conductor line electrically connecting two consecutive portions of the interconnection conductor track.

17. The photovoltaic string according to claim 12, wherein the first metallic connector comprises a plurality of disjointed portions welded to the first end shingle, each portion of the first metallic connector covering a surface of the front face of the first end shingle, called a portion of the first transfer surface.

18. The photovoltaic string according to claim 17, wherein each portion of the first transfer surface has a transfer width greater than each of the first and second coverage widths.

19. The photovoltaic string according to claim 12, wherein the first transfer surface has a first transfer width substantially equal to the first and second coverage widths.

20. The photovoltaic string of claim 12, further comprising:
a second metallic connector;
the second metallic connector being welded to the second end shingle, the second metallic connector covering a surface of the back face of the second end shingle, called the second transfer surface, the second metallic connector being welded to the second end shingle.

21. A method for manufacturing a photovoltaic string comprising:
providing a first photovoltaic cell forming a first end shingle, a second photovoltaic cell forming a second end shingle, a plurality of third photovoltaic cells forming intermediate shingles, and a first metallic connector, each of the first, second and third photovoltaic cells comprising a front face and a back face opposite to the front face;
interconnecting the first end shingle to a first intermediate shingle by a first electrically conductive adhesive, the back face of the first end shingle covering a first surface of the front face of the first intermediate shingle, called the first coverage surface, the first coverage surface having a first coverage width;
interconnecting a second intermediate shingle to the second end shingle by the first electrically conductive adhesive, the back face of the second intermediate shingle covering a surface of the front face of the second end shingle, called the second coverage surface, the second coverage surface having a second coverage width;
welding the first metallic connector to the first end shingle, the first metallic connector covering a surface of the front face of the first end shingle, called the first transfer surface.
